(19) United States
(12) Patent Application Publication
(10) Pub. No.: US 2026/0133456 A1
(43) Pub. Date: May 14, 2026

(54) DISPLAY DEVICE AND ELECTRONIC TERMINAL

(71) Applicant: TCL CHINA STAR OPTOELECTRONICS TECHNOLOGY CO., LTD., Shenzhen (CN)

(72) Inventors: Caifeng WEI, Shenzhen (CN); Chunfang QIU, Shenzhen (CN); Tuo FENG, Shenzhen (CN)

(73) Assignee: TCL CHINA STAR OPTOELECTRONICS TECHNOLOGY CO., LTD., Shenzhen (CN)

(21) Appl. No.: 19/023,637

(22) Filed: Jan. 16, 2025

(30) Foreign Application Priority Data
Nov. 8, 2024 (CN) 202411598513.7

(51) Int. Cl. G02F 1/1362; G02F 1/1368; G09G 3/36; H10D 86/40

(52) U.S. Cl. CPC G02F 1/136286; G02F 1/1368; H10D 86/441; G09G 3/3648; G09G 2300/0426; G09G 2300/0852; G09G 2320/0242

(57) ABSTRACT

The present disclosure provides a display device and an electronic terminal. A plurality of first pixels, a plurality of data lines, a plurality of sharing lines, and a plurality of first scan lines are provided in a display area. A second scan line is provided in a non-display area. Each sharing line is electrically connected to corresponding first pixels, and each data line is electrically connected to corresponding first pixels. The second scan line is electrically connected to an open first data line and a closed second data line of the plurality of data lines through a first node and a second node, respectively; and/or the second scan line is electrically connected to an open first sharing line and a closed second sharing line of the plurality of sharing lines through a third node and a fourth node, respectively.

### CROSS-REFERENCE TO RELATED APPLICATION

This application claims priority to Chinese Patent Application No. 202411598513.7, filed on Nov. 8, 2024. The disclosure of the aforementioned application is incorporated herein by reference in its entirety.

### TECHNICAL FIELD

The present disclosure relates to the field of display technologies, particularly to the technical field of display panel manufacturing, and specifically to a display device and an electronic terminal.

### BACKGROUND

In order to improve a yield rate of a display panel, for display problems such as line faults caused by a disconnection of signal lines of an original screen, the signal lines are generally reconditioned to achieve normal display of the original screen.

However, after laser of re-cutting the reconditioned original screen, some of the reconditioned lines may be cut, causing reappearance of the problems such as line faults that need to be reconditioned again. However, the above-mentioned repairing methods of the original screen are complicated and require a lot of laser work, which may reduce a manufacturing efficiency of the display panel.

### SUMMARY

In an aspect, embodiments of the present disclosure provide a display device, including a display panel including a display area and a non-display area. A plurality of first pixels, a plurality of data lines, a plurality of sharing lines, and a plurality of first scan lines are provided in the display area, a second scan line is provided in the non-display area, each of the sharing lines is electrically connected to corresponding ones of the plurality of first pixels, and each of the data lines is electrically connected to corresponding ones of the plurality of first pixels. The second scan line is electrically connected to an open first data line of the plurality of data lines through a first node, and is electrically connected to a closed second data line of the plurality of data lines through a second node; and/or the second scan line is electrically connected to an open first sharing line of the plurality of sharing lines through a third node, and is electrically connected to a closed second sharing line of the plurality of sharing lines through a fourth node.

In another aspect, embodiments of the present disclosure also provide an electronic terminal, including the display device as described in any one of the above.

### BRIEF DESCRIPTION OF THE DRAWINGS

FIG. 1 is a top view of a display device provided by embodiments of the present disclosure.

FIG. 2 is a circuit diagram of a first/second pixel provided by embodiments of the present disclosure.

FIG. 3 to FIG. 5 are layout diagrams of a display area provided by embodiments of the present disclosure.

FIG. 6 are schematic diagrams of an original screen provided by embodiments of the present disclosure, before cutting, after cutting, and with improvements after cutting.

### DETAILED DESCRIPTION

Technical solutions in embodiments of the present disclosure will be clearly and completely described below with reference to the accompanying drawings in the embodiments of the present disclosure. Obviously, the described embodiments are only some of the embodiments of the present disclosure, but not all of the embodiments. Based on the embodiments of the present disclosure, all other embodiments obtained by those skilled in the art without creative efforts shall fall within the scope of protection of the present disclosure.

The terms “first”, “second”, “third”, etc. in the present disclosure are used to distinguish different objects, rather than describing a specific sequence. Furthermore, the terms “include”, “comprise”, and “have” and any variations thereof are intended to cover non-exclusive inclusion. For example, a process, method, system, product or device that includes a series of steps or modules is not limited to the listed steps or modules, but optionally also includes steps or modules that are not listed, or optionally also includes other steps or modules inherent to such processes, methods, products or devices.

Reference herein to “embodiment” means that a particular feature, structure or characteristic described in connection with the embodiments can be included in at least one embodiment of the present disclosure. The appearances of this phrase in various places in the specification are not necessarily all referring to the same embodiment, nor are separate or alternative embodiments mutually exclusive of other embodiments. Those skilled in the art understand, both explicitly and implicitly, that the embodiments described herein may be combined with other embodiments.

Embodiments of the present disclosure provide a display device. The display device includes but is not limited to the following embodiments and combinations of the following embodiments.

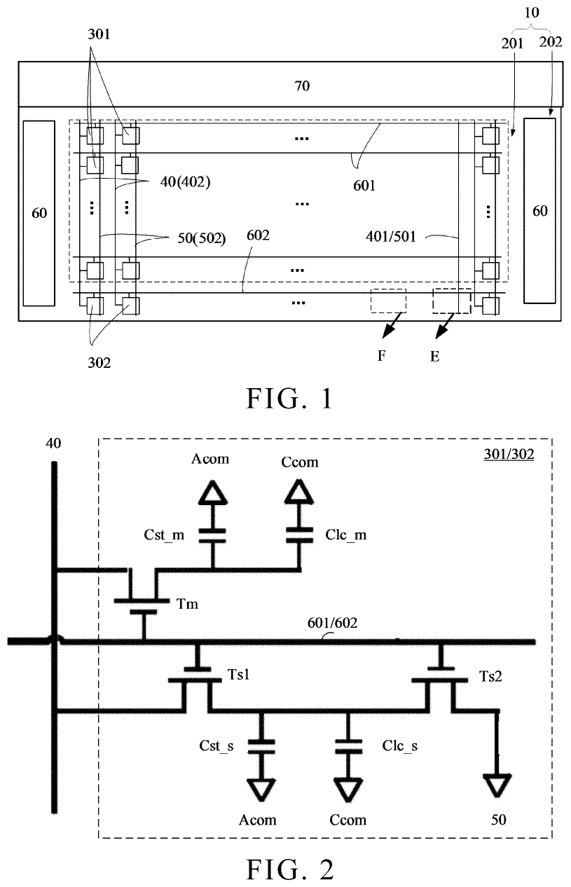

In some embodiments, as illustrated in FIG. 1 to FIG. 4, a display device 100 includes a display panel 10, including a display area 201 and a non-display area 202. A plurality of first pixels 301, a plurality of data lines 40, a plurality of sharing lines 50, and a plurality of first scan lines 601 are provided in the display area 201. At least one second scan line 602 is provided in the non-display area 202. Each of the sharing lines 50 is electrically connected to corresponding ones of the plurality of first pixels 301. Each of the data lines 40 is electrically connected to the corresponding ones of the plurality of first pixels 301. The at least one second scan line 602 is electrically connected to an open first data line 401 (which is an open circuit/disconnected) of the plurality of data lines 40 through a first node A, and is electrically connected to a closed second data line 402 (which is a closed circuit/non-disconnected) of the plurality of data lines 40 through a second node B; and/or, the at least one second scan line 602 is electrically connected to an open first sharing line 501 of the plurality of sharing lines 50 through a third node C, and is electrically connected to a closed second sharing line 502 of the plurality of sharing lines 50 through a fourth node D.

Specifically, as illustrated in FIG. 1, the display panel 10 may include a substrate and the above-mentioned first pixels 301, data lines 40, sharing lines 50, first scan lines 601, and second scan line 602 disposed on the substrate. Each first scan line 601 located in the display area 201 is electrically connected to corresponding ones of the plurality of first pixels 301, and each data line 40 located in the display area 201 is electrically connected to the corresponding ones of the plurality of first pixels 301. For example, the plurality of first pixels 301 are arranged in an array, the plurality of first scan lines 601 are respectively configured to transmit a plurality of gate signals to control multiple rows of the first pixels 301 to turn on in sequence. When the first pixels 301 in each row are turned on, the plurality of data lines 40 are respectively configured to output a plurality of data voltages to the first pixels 301 in said row. By analogy, the first pixels 301 in multiple rows are turned on and emit light in sequence.

The display panel 10 of the embodiments may be a liquid crystal display panel. In order to alleviate a problem of color shift of the liquid crystal display panel when viewed from a large viewing angle, as illustrated in FIG. 2, the first pixel 301 may include not only a main transistor Tm but also a first secondary transistor Ts1 and a second secondary transistor Ts2. Gates of the main transistor Tm, the first secondary transistor Ts1, and the second secondary transistor Ts2 are electrically connected to the first scan line 601. Sources of the main transistor Tm and the first secondary transistor Ts1 are electrically connected to the data line 40. A main storage capacitor Cst_m is formed between a drain of the main transistor Tm and an array side electrode Acom on the above-mentioned substrate of the display panel 10, and a main liquid crystal capacitor Clc_m is formed between a drain of the main transistor Tm and a color filter side electrode Ccom on a color filter substrate opposite to the substrate of the display panel 10. A secondary storage capacitor Cst_s is formed between a drain of the first secondary transistor Ts1 and the array side electrode Acom, and a secondary liquid crystal capacitor Clc_s is formed between the drain of the first secondary transistor Ts1 and the color filter side electrode Ccom. The secondary liquid crystal capacitor Clc_s is formed between a source of the secondary transistor Ts2 and the color filter side electrode Ccom. A drain of the second secondary transistor Ts2 is electrically connected to the corresponding sharing line 50.

For each first pixel 301, the gate signal transmitted by the first scan line 601 controls the main transistor Tm, the first secondary transistor Ts1, and the second secondary transistor Ts2 to turn on respectively; the data line 40 transmits the data voltage to the main storage capacitor Cst_m and the main liquid crystal capacitor Clc_m through the main transistor Tm, and also transmits the data voltage to the secondary storage capacitor Cst_s and the secondary liquid crystal capacitor Clc_s through the second secondary transistor Ts2; meanwhile, a sharing voltage transmitted by the sharing line 50 is also transmitted to the secondary storage capacitor Cst_s and the secondary liquid crystal capacitor Clc_s. In this way, a potential of the secondary storage capacitor Cst_s and a potential of the secondary liquid crystal capacitor Clc_s are different from a potential of the main storage capacitor Cst_m and a potential of the main liquid crystal capacitor Clc_m, and the above-mentioned potentials can also be maintained by the above-mentioned four capacitors, thereby maintaining the above-mentioned potential difference to achieve corresponding brightness difference, thereby improving the problem of color shift of the liquid crystal display panel when viewed from the large viewing angle.

In order to improve the uniformity in a structure and its resulted electrical characteristics of the plurality of first pixels 301, the plurality of data lines 40, the plurality of sharing lines 50, and the plurality of first scan lines 601 in the display area 201, it is also possible that the above-mentioned second scan line 602 and a plurality of second pixels 302 are provided in the non-display area 202. The second scan line 602 is electrically connected to or electrically disconnected from the second pixels 3. The data lines 40 and the sharing lines 50 can also extend into the non-display area 202. A circuit structure of the second pixel 302 may be the same as a circuit structure of the first pixel 301 as illustrated in FIG. 2. The data line 40 is electrically connected to or electrically disconnected from corresponding ones of the second pixels 302. The sharing line 50 is electrically connected to or electrically disconnected from corresponding ones of the second pixels 302. Different from the display area 201, the second scan line 602 in the non-display area 202 does not transmit a corresponding gate signal so as to prevent the second pixel 302 from emitting light. Therefore, when the second scan line 602 is configured to short the first data line 401 and the second data line 402 and/or to short the first sharing line 501 and the second sharing line 502, the second scan line 602 will not affect the data signals or sharing signals (including the above-mentioned sharing voltage) transmitted thereby.

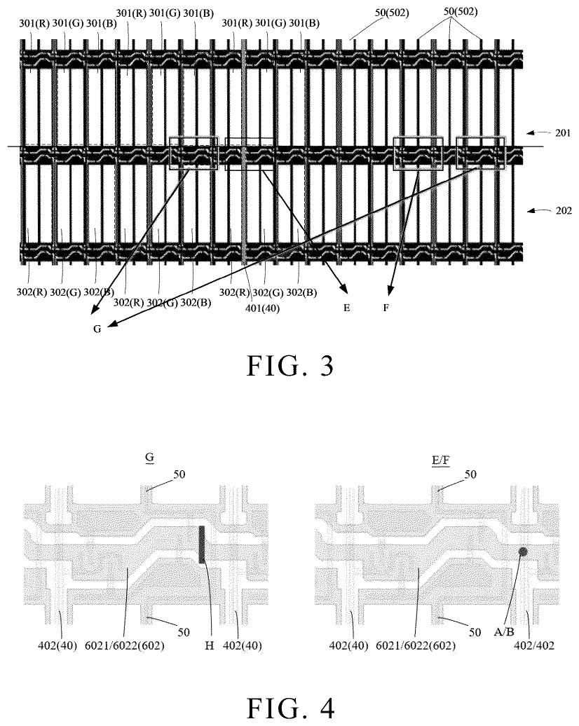

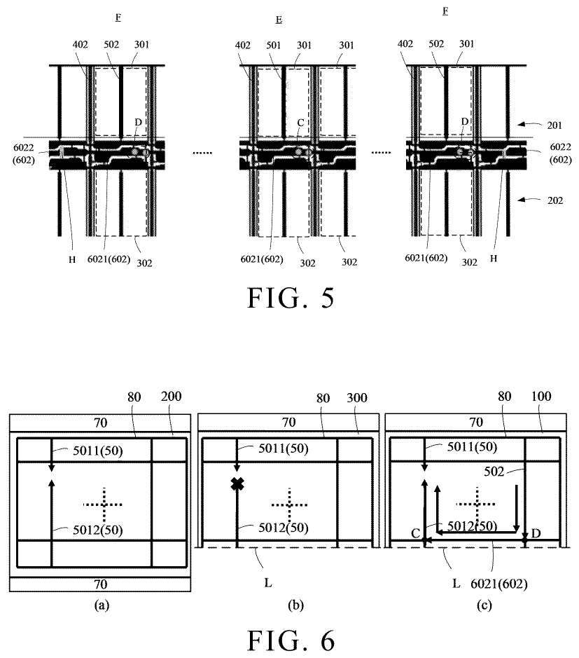

It should be noted that for re-cut display panels, laser re-cutting is generally performed on a reconditioned display panel, which may cut some of reconditioned lines (for example, an open-circuit area E in FIG. 1, FIG. 3 to FIG. 5), causing problems such as reappearance of line faults after being reconditioned. Based on this, the embodiments adopt a repairing method for the above-mentioned display panel 10 as follows. As illustrated in FIG. 1, FIG. 3, and FIG. 4, the first data line 401 that is disconnected in the open-circuit area E is electrically connected to the second scan line 602 through the first node A, and the second data line 402 that is not disconnected in the closed-circuit area F is electrically connected to the second scan line 602 through the second node B, so that the first data line 401 can still obtain the data signal transmitted by the second data line 402 through the second scan line 602, so as to realize a transmission of a corresponding data signal to multiple first pixels 301 in a corresponding column. As illustrated in FIG. 1 and FIG. 5, the second scan line 602 is electrically connected to the first sharing line 501 that is disconnected in the open-circuit area E through the third node C, and the second scan line 602 is electrically connected to the second sharing line 502 that is not disconnected in the closed-circuit area F through the fourth node D, so that the first sharing line 501 can still obtain the sharing signal (including the above-mentioned sharing voltage) transmitted by the second sharing line 502, so as to realize a transmission of a corresponding sharing signal to multiple first pixels 301 in a corresponding column.

It can be understood that the embodiments are aimed at the problem of that some of the reconditioned lines are cut in the display panel 10 formed after re-cutting. Different from more complicated repairing methods used to repair the original disconnected circuits before re-cutting (for example, two parts of a disconnected line are connected by laser), in the embodiments, the second scan line 602 in the non-display area 202 is used as a bridge to electrically connect the open first data line 401 to the closed second data line 402, and/or the second scan line 602 in the non-display area 202 is used as a bridge to electrically connect the open first sharing line 501 to the closed second sharing line 502, so that the open first data line 401 and/or the open first sharing line 501 can still transmit the corresponding data signal or the corresponding sharing signal, thereby improving the manufacturing efficiency of the display panel while realizing a repair of the disconnected line.

In some embodiments, as illustrated in FIG. 1, the display device 100 further includes a gate driving circuit 60. The first scan line 601 is electrically connected to the gate driving circuit 60, and the second scan line 602 is electrically disconnected from or electrically connected to the gate driving circuit 60. The gate driving circuit 60 may be disposed in the non-display area 202. For example, the second scan line 602 may be disposed in the non-display area 202 on an upper side and/or a lower side of the display area, and the gate driving circuit 60 may be disposed in the non-display area 202 on a left side and/or a right side of the display area. Based on the above discussion, it can be seen that the gate driving circuit 60 can be electrically connected to the plurality of first scan lines 601 to output a corresponding gate signal to each of the first scan lines 601 and to further transmit the corresponding gate signal to the first pixels 301 of the corresponding row, thereby turning on multiple rows of the first pixels 301 in sequence. As discussed above, the second scan line 602 in the non-display area 202 does not transmit a corresponding gate signal so that the second pixel 302 does not emit light. Specifically, the second scan line 60 (electrically connected to the first data line 401 or the first sharing line 501) is electrically disconnected from the gate drive circuit 60, or the second scan line 602 is electrically connected to the gate drive circuit 60, but the gate drive circuit 60 does not output a gate signal to the second scan line 602.

When the second scan line 602 and the gate driving circuit 60 are electrically disconnected, the second scan line 602 can be considered to be in a floating state, so it can be used to transmit the data signal to the first data line 401, and/or transmit the sharing signal to the first sharing line 501.

When the second scan line 602 is electrically connected to the gate driving circuit 60 but the gate driving circuit 60 does not output the gate signal to the second scan line 602, it can be considered that: the gate driving circuit 60 includes a plurality of cascaded gate driving units (not shown), and the plurality of gate driving units include a plurality of first gate driving units and at least one second gate driving unit; the gate driving unit is electrically connected to one corresponding first scan line 601 or one corresponding second scan line 602, that is, the first gate driving unit is electrically connected to one corresponding first scan line 601, and the second gate driving unit is electrically connected to the corresponding second scan lines 602; and the gate driving unit corresponding to the second scan line 602 electrically connected to the first data line 401 or the first sharing line 501 is electrically disconnected from another gate driving unit at an adjacent stage electrically connected to the first scan line 601, that is, the second gate driving unit corresponding to the second scan line 602 electrically connected to the first data line 401 or the first sharing line 501 is electrically disconnected from the first gate driving unit at the adjacent stage.

That is to say, although the gate driving circuit 60 does not output the gate signal to the second scan line 602 in this case, the data signal or sharing signal transmitted by the second scan line 602 may be transmitted to the gate driving unit at the adjacent stage electrically connected to the first scan line 601 through the gate driving unit corresponding to the second scan line 602, thereby affecting the gate signal output by the gate driving unit electrically connected to the first scan line 601. Therefore, the gate driving unit electrically connected to the second scan line 602 and the gate driving unit electrically connected to the first scan line 601 can be electrically disconnected, so as to present the data signal and/or the sharing signal transmitted by the second scan line 602 from being reversely transmitted to the gate driving unit electrically connected to the first scan line 601, thereby avoiding affecting the gate signal, which is output by the gate driving unit, acting on the first scan line 601.

In some embodiments, as shown in FIG. 4 and FIG. 5, the second scan line 602 includes a first sub-line 6021 and a second sub-line 6022 electrically disconnected from the first sub-line 6021. The first sub-line 6021 is electrically connected to the first data line 401 or the first sharing line 501, and is electrically connected to the second data line 402 or the second share line 502. The second sub-line 6022 is electrically connected to or electrically disconnected from the gate driving circuit 60.

Specifically, as illustrated in FIG. 3 and FIG. 4, the first sub-line 6021 can be electrically connected to the first data line 401 that is disconnected in the open-circuit area E through the first node A, and can be electrically connected to the second data line 402 that is not disconnected in the closed-circuit area F through the second node B. It can be considered that the second scan line 602 may be disconnected by, for example, laser, to form the first sub-line 6021 and the second sub-line 6022 which are independent of each other, and the first sub-line 6021 and the second sub-line 6022 are disconnected through a breaking point H. Therefore, it can be considered that the second sub-line 6022 does not transmit the data signal or the sharing signal, so whether it is electrically connected to or electrically disconnected from the gate driving circuit 60, it will not affect the gate signal output by the gate driving circuit 60 to the first scan line 601.

In some embodiments, as shown in FIG. 1 and FIG. 6, the display device 100 further includes a chip 70 located on one side of the display panel 10, and the chip 70 transmits the sharing signals to the plurality of sharing lines 50 through peripheral wirings 80. When the second scan line 602 is electrically connected to the first sharing line 501 through the third node C and electrically connected to the second sharing line 502 through the fourth node D, the first sharing line 501 includes a first sharing sub-line 5011 and a second sharing sub-line 5012 electrically disconnected from each other. The first sharing sub-line 5011 close to the chip 70 is electrically connected to the chip 70, and the second sharing sub-line 5012 far away from the chip 70 is electrically connected to the second scan line 602.

An original screen 200 before re-cutting shown as (a) in FIG. 6 is provided with chips 70 correspondingly on two opposite sides. The original screen 200 includes peripheral wirings 80 arranged along a periphery and electrically connected to the chips 70 on an upper side and a lower side, respectively. In this case, even if the sharing line 50 is disconnected and becomes the first sharing sub-line 5011 and the second sharing sub-line 5012, both of them can obtain the sharing signals through corresponding parts of the peripheral wirings 80. That means, all sharing signals are the same.

However, for a cutting screen 300 after re-cutting along a cutting line L shown as (b) in FIG. 6, the second sharing sub-line 5012 close to the lower side can no longer be electrically connected to the peripheral wirings 80 and the chip 70, because, for example, a part of the original screen 200 close to the lower side and the chip 70 on the lower side are cut, so that multiple first pixels 301 electrically connected thereto are unable to obtain the corresponding sharing signal.

It can be understood that, shown as (c) in FIG. 6, in the embodiments, on the basis that the first sharing sub-line 5011 close to the chip 70 is electrically connected to the chip 70, the second sharing sub-line 5012 far away from the chip 70 is electrically connected to the second scan line 602 (to the first sub-line 6021, if the first sub-line 6021 exists) through the third node C, and the second scan line 602 is electrically connected to the second sharing line 502 through the fourth node D, so that the sharing signal is transmitted by the second scan line 602 through the second sharing line 502 to the second sharing sub-line 5012.

Specifically, as illustrated in FIG. 3, the plurality of first pixels 301 include first sub-pixels R, second sub-pixels G, and third sub-pixels B with different colors. The sharing line 50 is electrically connected to corresponding ones of the plurality of first sub-pixels R, corresponding ones of the plurality of second sub-pixels G, or corresponding ones of the plurality of third sub-pixels B. As illustrated in FIG. 3 and FIG. 5, the first pixels 301 electrically connected to the first sharing line 501 and the first pixels 301 electrically connected to the second sharing line 502 are all the first sub-pixels R, the second sub-pixels G, or the third sub-pixels B; or, the first pixels 301 electrically connected to the first sharing line 501 and the first pixels 301 electrically connected to the second sharing line 502 are respectively different two among the first sub-pixels R, the second sub-pixels G, and the third sub-pixels B.

This embodiment is on the basis that the first pixels 301 in each column are the first sub-pixels R, the second sub-pixels G, or the third sub-pixels B with the same color. That is, on the basis that one column of the first pixels 301 electrically connected to the sharing line 50 have the same color. Considering that electrical characteristics of the first pixels 301 with the same color are similar, the second sharing line 502 corresponding to one column of the first pixels 301 with the same color as one corresponding column of the first pixels 301 of the first sharing line 501 can be electrically connected to the first sharing line 501, so that the one column of first pixels 301 corresponding to the first sharing line 501 can obtain a sharing signal with proximity theoretical electrical characteristics thereof. On the other side, considering that all sharing signals are the same, it is also possible that the second sharing line 502 corresponding to the first pixels 301 with other colors is also electrically connected to the first sharing line 501.

It should be noted that, considering a risk of signal attenuation, the second sharing line 502 that is relatively close to the first sharing line 501 can be electrically connected to the first sharing line 501 through the second scan line 602 to improve a transmission reliability of the sharing signal.

In some embodiments, as illustrated in FIG. 1, a chip 70 (which may be the same as or different from the above-mentioned chip 70, and which at least includes a source driver chip) also transmits the corresponding above-mentioned data signals to the data lines 40. Combined with FIG. 3 and FIG. 4, when the second scan line 602 is electrically connected to the first data line 401 through the first node A and electrically connected to the second data line 402 through the second node B, similar to the first sharing sub-line 5011 and the second sharing sub-line 5012 in FIG. 6, the first data line 401 includes a first data sub-line and a second data sub-line (not shown) electrically disconnected from each other. The first sub-data line close to the chip 70 is electrically connected to the source driver chip, and the second sub-data line far away from the source driver chip is electrically connected to the second scan line 602.

Unlike the chip 70 that transmits the sharing signals to the plurality of sharing lines 50 through the peripheral wirings 80, the chip 70 (i.e., the source driver chip thereof) in this embodiment directly transmits multiple corresponding data signals to the plurality of data lines 40, respectively. However, in the original screen 200 before re-cutting shown as (a) in FIG. 6, even if the data line 40 is disconnected and includes the first sub-data line and the second sub-data line, both of them can obtain the same data signal through the two chips 70 (i.e., the source driver chip thereof) on both sides, respectively.

Similarly, shown as (c) in FIG. 6, in this embodiment, on the basis that the first sub-data line close to the chip 70 is electrically connected to the chip 70, the second sub-data line far away from the chip 70 is electrically connected to the second data line 402 through the second scan line 602 (through the first sub-line 6021, if the first sub-line 6021 exists), so that the data signal is transmitted from the second data line 402 to the second data sub-line through the second scan line 602.

In some embodiments, as illustrated in FIG. 3, at least two of the plurality of first pixels 301 have different colors, and multiple first pixels 301 electrically connected to the same data line 40 have the same color. The color of the first pixels 301 corresponding to the first data line 401 and the color of the first pixels 301 corresponding to the second data line 402 electrically connected to the first data line 401 are the same. For example, the plurality of first pixels 301 include the above-mentioned first sub-pixels R, second sub-pixels G, and third sub-pixels B, and the data line 40 is electrically connected to corresponding ones of the plurality of first sub-pixels R, corresponding ones of the plurality of second sub-pixels G, or corresponding ones of the plurality of third sub-pixel B. The first pixels 301 electrically connected to the first data line 401 and the first pixels 301 electrically connected to the second data line 402 are the first sub-pixels R, the second sub-pixels G, or the third sub-pixels B.

It can be understood that this embodiment is on the basis that the first pixels 301 in each column are the first sub-pixels R, the second sub-pixels G, or the third sub-pixels B with the same color, that is, on the basis that each data line 40 is electrically connected to one column of the first pixels 301 with the same color. Considering that loaded data signals of the first pixels 301 with the same color are similar so as to display similar color, the second data line 402 corresponding to one column of the first pixels 301 with the same color as the first pixels 301 of one corresponding column of the first data line 401 can be electrically connected to said first data line 401, so that the first pixels 301 corresponding to the first data line 401 401 can obtain the data signal with proximity theoretical electrical characteristics thereof.

In one aspect, considering the risk of signal attenuation, the second data line 402 that is relatively close to the first data line 401 can be electrically connected to the first sharing line 501 through the second scan line 602 to improve a transmission reliability of the data signal. For example, the second data line 402 electrically connected to the first data line 401 is separated from the first data line 401 by up to n data lines 40, where n is 0 or a positive integer, which can be set according to actual situations, such as less than or equal to 3, or less than or equal to 4. In another aspect, since optical properties and electrical characteristics of the first pixels 301 with different colors are greatly different, considering that luminous colors of the first pixels 301 with the same color in a nearby area are relatively similar, the first data line 401 and the second data line 402 corresponding to the first pixels 301 with the same color can be electrically connected.

In other pixel arrangements, such as a tri-gate architecture, since the first pixels 301 in the same row have the same color, the data voltages transmitted by adjacent data lines 40 during a same period correspond to the first pixels 301 with the same color. Therefore, it is only necessary to electrically connect the first data line 401 to any second data line 402 that is relatively close.

Embodiments of the present disclosure also provide an electronic terminal, including the display device as described in any one of the above embodiments.

The display device and the electronic terminal provided by the embodiments of the present disclosure have been introduced in detail above. Specific examples are used in this paper to illustrate the principles and implementations of the present disclosure. The description of the above embodiments is only used to help understand technical solutions and core ideas of the present disclosure. Those of ordinary skill in the art should understand that they can still modify the technical solutions recorded in the foregoing embodiments, or make equivalent substitutions for some of the technical features; and these modifications or substitutions do not deviate the essence of corresponding technical solutions from a scope of the technical solution of embodiments of the of the present disclosure.

What is claimed is:

1. A display device, comprising a display panel, wherein the display panel comprises a display area and a non-display area, a plurality of first pixels, a plurality of data lines, a plurality of sharing lines, and a plurality of first scan lines are provided in the display area, a second scan line is provided in the non-display area, each of the sharing lines is electrically connected to corresponding ones of the plurality of first pixels, and each of the data lines is electrically connected to corresponding ones of the plurality of first pixels; and
wherein the second scan line is electrically connected to an open first data line of the plurality of data lines through a first node, and is electrically connected to a closed second data line of the plurality of data lines through a second node; and/or
the second scan line is electrically connected to an open first sharing line of the plurality of sharing lines through a third node, and is electrically connected to a closed second sharing line of the plurality of sharing lines through a fourth node.

2. The display device according to claim 1, further comprising a gate driving circuit, wherein the first scan lines are electrically connected to the gate driving circuit, and the second scan line is electrically disconnected from or electrically connected to the gate driving circuit.

3. The display device according to claim 2, the second scan line comprises a first sub-line electrically connected to the first data line or the first sharing line, and comprises a second sub-line electrically disconnected from the first sub-line, and the second sub-line is electrically connected to or electrically disconnected from the gate driving circuit.

4. The display device according to claim 3, wherein the first sub-line is electrically connected to the first data line or the first sharing line through the first node or the third node, and electrically connected to the second data line or the second sharing line through the second node or the fourth node, and the second sub-line does not transmit a gate signal.

5. The display device according to claim 2, wherein the second scan line electrically connected to the first data line or the first sharing line is electrically disconnected from the gate driving circuit.

6. The display device according to claim 2, wherein the gate driving circuit comprises a plurality of first gate driving units and a second gate driving unit, each of the first gate driving units is electrically connected to a corresponding one of the first scan lines, and the second gate driving unit is electrically connected to the second scan line; and
the second gate driving unit corresponding to the second scan line electrically connected to the first data line or the first sharing line is electrically disconnected from one of the first gate driving units at an adjacent stage.

7. The display device according to claim 2, wherein the second scan line comprises a first sub-line electrically connected to the first data line or the first sharing line and comprises a second sub-line electrically disconnected from the first sub-line, and the second sub-line is electrically connected to or electrically disconnected from the gate driving circuit.

8. The display device according to claim 1, further comprising a chip disposed on one side of the display panel, wherein the chip is configured to transmit sharing signals to the plurality of sharing lines through peripheral wirings; and
the second scan line is electrically connected to the first sharing line through the third node and electrically connected to the second sharing line through the fourth node, the first sharing line comprises a first sharing sub-line and a second sharing sub-line electrically disconnected from each other, the first sharing sub-line close to the chip is electrically connected to the chip, and the second sharing sub-line far away from the chip is electrically connected to the second scan line.

9. The display device according to claim 1, further comprising a source driver chip disposed on one side of the display panel, wherein the source driver chip is configured to transmit a corresponding data signal to each of the data lines; and
the second scan line is electrically connected to the first data line through the first node and electrically connected to the second data line through the second node, the first data line comprises a first data sub-line and a second data sub-line electrically disconnected from each other, the first data sub-line close to the source driver chip is electrically connected to the source driver chip, and the second data sub-line far away from the source driver chip is electrically connected to the second scan line.

10. The display device according to claim 9, wherein at least two of the plurality of first pixels have different colors, the first pixels electrically connected to a same one of the data lines have a same color; and
the first pixels corresponding to the first data line and the first pixels corresponding to the second data line electrically connected to the first data line have a same color.

11. The display device according to claim 10, wherein the second data line electrically connected to the first data line is separated from the first data line by up to n data lines, where n is 0 or a positive integer less than or equal to 4.

12. The display device according to claim 1, further comprising a plurality of second pixels disposed the non-display area, the data lines and the sharing lines also extend into the non-display area, each of the data lines is electrically connected to or electrically disconnected from corresponding ones of the second pixels, and each of the sharing lines is electrically connected to or electrically disconnected from corresponding ones of the second pixels; and
the second scan line is electrically connected to or electrically disconnected from the second pixels, and the second scan line does not transmit gate signals to the second pixels.

13. The display device according to claim 1, wherein each of the first pixels comprises a main transistor, a first secondary transistor, and a second secondary transistor;
gates of the main transistor, the first secondary transistor, and the second secondary transistor are electrically connected to a corresponding one of the first scan lines;
sources of the main transistor and the first secondary transistor are electrically connected to a corresponding one of the data lines;
a main storage capacitor is formed between a drain of the main transistor and an array side electrode of the display panel;
a main liquid crystal capacitor is formed between a drain of the main transistor and a color filter side electrode of the display panel;
a secondary storage capacitor is formed between a drain of the first secondary transistor and the array side electrode;
a secondary liquid crystal capacitor is formed between the drain of the first secondary transistor and the color filter side electrode and also formed between a source of the secondary transistor and the color filter side electrode; and
a drain of the second secondary transistor is electrically connected to a corresponding one of the sharing lines.

14. The display device according to claim 13, wherein a potential of the secondary storage capacitor and a potential of the secondary liquid crystal capacitor are different from a potential of the main storage capacitor and a potential of the main liquid crystal capacitor.

15. The display device according to claim 14, wherein the corresponding one of the first scan lines is configured to transmit a gate signal to control the main transistor, the first secondary transistor, and the second secondary transistor to turn on respectively;
the corresponding one of the data lines is configured to transmit a data voltage to the main storage capacitor and the main liquid crystal capacitor through the main transistor, and is configured to transmit a data voltage to the secondary storage capacitor and the secondary liquid crystal capacitor through the second secondary transistor; and
the corresponding one of the sharing lines is configured to transmit a sharing voltage to the secondary storage capacitor and the secondary liquid crystal capacitor.

16. An electronic terminal, comprising the display device of claim 1.
